(19) United States
(12) Patent Application Publication
(10) Pub. No.: US 2026/0134626 A1
(43) Pub. Date: May 14, 2026

(54) APPLICATIONS OF FUZZY LOGIC TO THIN REGION DETECTION IN MESH GENERATION

(71) Applicant: Siemens Industry Software Inc., Plano, TX (US)

(72) Inventors: Davide Detomi, Roma (IT); Scott Canann, Austin, TX (US); Kenneth Blake, Austin, TX (US)

(21) Appl. No.: 19/118,430

(22) PCT Filed: Nov. 10, 2022
(86) PCT No.: PCT/US2022/049486

§ 371 Date: Apr. 4, 2025

(51) Int. Cl. G06T 17/20; G06F 30/23; G06F 30/28

(52) U.S. Cl. CPC G06T 17/20; G06F 30/23; G06F 30/28

(57) ABSTRACT

A computer-implemented method of generating a thin volume mesh in a Computer-Aided technology (CAx) model of an object is described. In the method, a volume region lying between a first surface mesh having a first set of mesh parameters and a second surface mesh having a second set of mesh parameters is selected. This volume region has a thickness corresponding to the distance between the first and second surface mesh. prismatic cell volume mesh is generated to fill the entire volume region when the volume region is thin. Whether or not the volume region is thin is given by a crisp value calculated using a fuzzy logic inference scheme including the fuzzy sets thin and non-thin, and wherein the relationship between the first and second sets of mesh parameters and the thickness determine the membership of the fuzzy sets thin and non-thin.

The present patent document is a § 371 nationalization of PCT Application Serial No. PCT/US2022/049486, filed Nov. 10, 2022, designating the United States, which is hereby incorporated by reference in its entirety.

### TECHNICAL FIELD

The present disclosure relates to a computer-implemented method of generating a thin volume mesh in a model of an object.

### BACKGROUND

Computational fluid dynamics (CFD) simulations may rely on meshing techniques as part of finite element analysis or finite volume methods to enable the calculation of the transport of physical quantities on a discretized mesh. For example, Simcenter STAR-CCM+, available from Siemens AG (www.siemens.com), integrates meshing techniques along with CAD (Computer Aided Design), Multiphysics CFD, and design exploration as part of the design process. Meshing is particularly advantageous for CFD modelling, because it requires less computational investment than other surface and volume generating modelling techniques. The meshing process itself is the result of many different combinations of algorithms and data, all of which may be valid. Accepting a mesh modification or performing a specific action among a group of specific choices may be the result of a comparison between a stored value and a hardcoded threshold. Any complex meshing algorithm is full of such comparisons, each of which may or may not lead to an optimal result and may be chosen based on the experience of the user. Alternatively, such choices may be the result of extensive testing, which covers many, but not all, of the possible scenarios, where the values are tuned progressively to find the best possible (or most reasonable) compromise. In addition, during any given meshing run, it is common for a variable to hold a value that is very close to a threshold, thus leading to decisions that may have been completely different if a small perturbation had been introduced in any upstream processing. Such perturbations may happen easily as the consequence of code evolution over time.

One way of dealing with such issues would be to introduce human decision making into the process. However, this is incompatible with hardcoded constant thresholds, and difficult to implement in a complex downstream calculation, such as CFD. There is therefore a need to overcome such issues, to be able to improve the overall performance of meshing techniques and consequently the modelling of physical quantities and qualities in product design.

### SUMMARY

The scope of the present disclosure is defined solely by the appended claims and is not affected to any degree by the statements within this summary. The present embodiments may obviate one or more of the drawbacks or limitations in the related art.

The present disclosure aims to address these issues by providing, in a first aspect, a computer-implemented method of generating a thin volume mesh in a Computer-Aided technology (CAx) model of an object. The method includes selecting a volume region lying between a first surface mesh having a first set of mesh parameters and a second surface mesh having a second set of mesh parameters, the volume region having a thickness t corresponding to the distance between the first and second surface mesh. The method further includes generating a prismatic cell volume mesh to fill the entire volume region when the volume region is thin. Whether or not the volume region is thin is given by a crisp value calculated using a fuzzy logic inference scheme including the fuzzy sets thin and non-thin. Further, the relationship between the first and second sets of mesh parameters and the thickness t determine the membership of the fuzzy sets thin and non-thin.

By using a fuzzy logic approach to determining the nature of volumes within an object in a CAx model, the need to have a human decision on quantifying “thin” or “non-thin,” and therefore whether a prismatic volume mesh may be used to fill the volume is removed. This leads to subsequent CFD modelling of higher accuracy due to the improved quality of the mesh volumes generated.

Determining the fuzzy membership of the fuzzy sets may include: selecting a source point S on the first surface mesh where the volume mesh is required, measuring the surface mesh size SS at the source point, and calculating a deviation ρ_{S} of a triangle of the surface mesh at the source point S from a reference equilateral triangle; and selecting a target point T on the second surface mesh by extending a ray along the local normal from the source point, measuring the surface mesh size TS at the target point, and calculating a deviation ρ_{T} of a triangle of the surface mesh at the target point T from a reference equilateral triangle. If the ratios SS/t and TS/t are above a first reference value and a second reference value, the volume region is in the thin fuzzy set. If the deviation ρ_{S} or the deviation β_{T} is above a third reference value, then the volume region is in the non-thin fuzzy set.

The first and second reference values, respectively, may be given by:

$${( \frac{S}{t} )}_{a} = \frac{2}{{e}^{- σ + ln ( 1 + p )} + 1 - p} \\ and$$

$${( \frac{S}{t} )}_{b} = \frac{2}{{e}^{- \overline{PF} + l n ( 1 + p )} + 1 - p} .$$

The third reference value is given by:

$$\overline{ρ} = 1.8 .$$

In these equations, S is the local mesh size of the first surface mesh, t is the thickness of the volume region, a is the standard deviation of the S/t ratio over the surface of the first surface mesh, P̅F̅ is

$$\frac{1 - PF}{max ( ε , P F )} ,$$

where ε=10⁻⁴ and PF is the percentage of vertices on the first surface mesh that are locally thin, and p is a penalty factor.

The method may also include: combining plots representing the membership of the thin fuzzy set with a plot representing the membership of the non-thin fuzzy set graphically using an OR operator; calculating the center-of-weight of the area under the curve of the combined plots; and taking the center-of-weight as the crisp value.

The object may include a thin sheet or a thin wall.

The model may be a computational fluid dynamics (CFD) model.

The fuzzy logic inference scheme may be the Mamdani inference scheme.

In certain examples, the thin volume mesh may not contain arbitrary volume cells.

The present disclosure also provides, in a second aspect, a computer program including instructions that, when executed by a computer processor of a computer, cause the computer to carry out the acts of the method outlined above.

The present disclosure also provides, in a third aspect, a data processing system configured to generate a thin volume mesh in a Computer-Aided technology (CAx) model of an object. The data processing system includes an input device configured to receive a selection of a volume region lying between a first surface mesh having a first set of mesh parameters and a second surface mesh having a second set of mesh parameters, the volume region having a thickness t corresponding to the distance between the first and second surface mesh. The data processing system further includes a processor configured to generate a prismatic cell volume mesh to fill the entire volume region. Whether or not the volume region is thin is given by a crisp value calculated by the processor using a fuzzy logic inference scheme including the fuzzy sets thin and non-thin. Further, the relationship between the first and second sets of mesh parameters and the thickness t determine the membership of the fuzzy sets thin and non-thin.

### BRIEF DESCRIPTION OF THE DRAWINGS

The present disclosure is now described by way of example only, and with reference to the accompanying drawings, in which:

FIG. 1 depicts an example of a plot showing values of (S/t) against (σ, F̅P̅).

FIG. 2 depicts an example of a mesh section where the thinness needs to be determined.

FIG. 3 depicts a plot of a first membership function for the property “is thin” in accordance with embodiments of the present disclosure.

FIG. 4 depicts a plot of a second membership function for the property “is thin” in accordance with embodiments of the present disclosure.

FIG. 5 depicts a plot of a membership function for the property “is not thin” in accordance with embodiments of the present disclosure.

FIG. 6a depicts an example of a plot of non-thin vs thin based on the value of the membership function for non-thin.

FIG. 6b depicts an example of a plot of non-thin vs thin based on the values of the membership functions for thin.

FIG. 6c depicts an example of a combined plot of non-thin and thin for the location under analysis.

FIG. 7 depicts a flowchart of a method in accordance with the embodiments of the present disclosure.

FIG. 8a depicts an example of a perspective view of a three-dimensional curved thin sheet having meshed surfaces modelled using hardcoded tolerances.

FIG. 8b depicts a perspective view of a three-dimensional curved thin sheet having meshed surfaces modelled using the embodiments of the present disclosure;

FIG. 8c depicts an alternative perspective view of a portion of the thin sheet shown in FIG. 8a.

FIG. 8d depicts an alternative perspective view of a portion of the thin sheet shown in FIG. 8b.

FIG. 8e depicts an alternative perspective view of a portion of the thin sheet shown in FIG. 8a.

FIG. 8f depicts an alternative perspective view of a portion of the thin sheet shown in FIG. 8b.

FIG. 9a depicts an example of a perspective view of a three-dimensional complex component having meshed surfaces modelled using hardcoded tolerances.

FIG. 9b depicts a perspective view of a three-dimensional complex component having meshed surfaces modelled using the embodiments of the present disclosure.

FIG. 9c depicts an alternative perspective view of a portion of the component shown in FIG. 9a.

FIG. 9d depicts an alternative perspective view of a portion of the component shown in FIG. 9b.

FIG. 9e depicts an alternative perspective view of a portion of the component shown in FIG. 9a.

FIG. 9f depicts an alternative perspective view of a portion of the component shown in FIG. 9b.

FIG. 10 illustrates an example of a data processing system in which an embodiment of the present disclosure may be implemented, for example, a CAx system configured to perform processes as described herein.

### DETAILED DESCRIPTION

Other than human intervention, techniques to make decisions include fuzzy logic, which introduces flexibility by intelligently relaxing fixed criteria boundaries. Fuzzy logic is a more human-like approach to decide the truth of a given statement, whilst keeping the rules that stand behind classical “sharp” logic, such as commutativity, associativity, distributivity, and transitivity. Following the development of fuzzy logic in the 1960s, it has been explored and expanded to many different fields, including facial recognition weather forecasting and subway control, to name but a few. However, as yet such techniques have not been employed extensively in areas such as meshing. The embodiments take the benefits of fuzzy logic and apply them to the decision process in a specialized mesher within a CAx (Computer-Aided technology) model that has been designed to recognize and treat arbitrarily complex geometries within locally thin regions properly. Locally thin regions occur in objects such as thin sheets and thin walls, particularly those used in fluid flow applications, including pipes, aerofoils, and cooling devices, to name but a few. This is done by initially selecting a volume region lying between a first surface mesh having a first set of mesh parameters and a second surface mesh having a second set of mesh parameters. The volume region has a thickness t corresponding to the distance between the first and second surface mesh. If the volume region is thin, a prismatic cell volume mesh will be generated to fill the entire volume region. Whether or not the volume region is thin is given by a crisp value calculated using a fuzzy logic inference scheme including the fuzzy sets thin and non-thin, and wherein the relationship between the first and second sets of mesh parameters and the thickness t determine the membership of the fuzzy sets thin and non-thin. This methodology is described in more detail below.

### Fuzzy Logic

By way of background, fuzzy logic concepts employed by the embodiments are now described. Consider the crisp set X containing three items:

$$X = \{ {x}_{1} , {x}_{2} , {x}_{3} \}$$

A subset Y={x₂} may be expressed through the concept of membership associated to each item of X. In sharp or Boolean logic, this is a value that may either be 0 (the item is not within the subset) or 1 (the item is contained within the subset):

$$Y = \{ ( {x}_{1} , 0 ) , ( {x}_{2} , 1 ) , ( {x}_{3} , 0 ) \}$$

When rendered in fuzzy logic, the subset becomes:

$$Y = \{ ( {x}_{1} , {μ}_{Y} ( {x}_{1} ) ) , ( {x}_{2} , {μ}_{Y} ( {x}_{2} ) ) , ( {x}_{3} , {μ}_{Y} ( {x}_{3} ) ) \}$$

where 0≤μ_{γ}(x)≤1 is a membership function.

An item may belong to the subset Y partially, which is a completely new property with respect to sharp logic. All of the standard properties (such as commutativity, associativity, distributivity, idempotency, transitivity) still hold, and suitable generalizations are possible for all of the known operations on sets. Three examples of this are given below.

### (Example 1) Complement

Boolean logic: who does not belong to the set?
Fuzzy logic: how much do elements not belong to the set?

Hence, if A is defined as:

$$A = \{ ( {x}_{1} , {μ}_{A} ( {x}_{1} ) ) , ( {x}_{2} , {μ}_{A} ( {x}_{2} ) ) , ( {x}_{3} , {μ}_{A} ( {x}_{3} ) ) \}$$

The complementary set is defined as:

$$not ( A ) = \{ ( {x}_{1} , 1 - {μ}_{A} ( {x}_{1} ) ) , ( {x}_{2} , 1 - {μ}_{A} ( {x}_{2} ) ) , ( {x}_{3} , 1 - {μ}_{A} ( {x}_{3} ) ) \}$$

### (Example 2) Intersection

Boolean logic: which element belongs to both sets?
Fuzzy logic: how much of the element is in both sets?

Hence, if A={(x, μ_{A} (x))} and B={(x, μ_{B} (x))}, their intersection is defined as:

$$A ⋂ B = \{ ( x , {μ}_{A ∩ B} ( x ) ) \} = min [ {μ}_{A} ( x ) , {μ}_{B} ( x ) ] = {μ}_{A} ( x ) ⋂ {μ}_{B} ( x )$$

### (Example 3) Union

Boolean logic: which element belongs to either set?
Fuzzy logic: how much of the element is in either set?
Hence, if A={(x, μ_{A}(x))} and B={(x, μ_{B} (x))}, their union is defined as:

$$A ⋃ B = \{ ( x , {μ}_{A ⋃ B} ( x ) ) \} = max [ {μ}_{A} ( x ) , {μ}_{B} ( x ) ] = {μ}_{A} ( x ) ⋃ {μ}_{B} ( x )$$

The most commonly used fuzzy interference technique is the so-called Mamdani method, which may be summarized as follows:

| | Act | Action |
|---|---|---|
| 1 | Define the parameters | Identification of all reference parameters |
| | | may drive decisions. The parameters may be |
| | | comparable or unrelated, but are meaningful |
| | | with respect to the target decision. |
| 2 | Define the fuzzy | Once found, the relevant parameters may be |
| | statements and set any | used within suitable statements that define |
| | required fuzzy | the problem rules. In order to perform the |
| | definition | comparisons practically, each statement may |
| | | require the specification of some additional |
| | | fuzzy definitions. |
| 3 | Define the target | The problem rules may finally lead to one or |
| | decision | more final decisions. |
| 4 | Gathering the partial | Any fuzzy statement may work as a black |
| | results from the fuzzy | box that has crisp values as input and |
| | statements | returns a fuzzy value. All such fuzzy values |
| | | are gathered to be properly combined and |
| | | evaluated. |
| 5 | Combining the partial | By combining fuzzy values, the algorithm |
| | results to provide a | may make a final, crisp, decision |
| | final answer for the | |
| | target decision | |

The application of such techniques to “thin meshing” in the embodiments is now described. Thin meshing is the process of finding locally thin (e.g., below a threshold determined by the mesh geometry) sections in a mesh and creating well-shaped prism meshes through the thin section, which also requires good alignment of mesh faces across the thin section to create such well-shaped elements. Filling regions of a model with prismatic cells produces a better result than merely using arbitrary volume cells. However, doing so may be high in terms of computational costs, and therefore finding an ideal compromise between the numerical accuracy of determining what is and is not a thin mesh section and the computational costs required is of great importance.

### Fuzzy Parameters, Definitions and Rules for Thin Meshing

The following definitions are used in the description.

Source Sizing (SS) refers to the local surface mesh size at a specific location (Source) where the model thinness is being checked.

Target Sizing (TS) refers to the size of the surface mesh at the nearby intersection point (Target) between the surface mesh and a ray shot from the Source point along its local normal direction.

Thickness (t) refers to the length of the segment between the Source and the Target points.

$$ρ = \frac{1}{2} \frac{{R}_{c i r c u m}}{{r}_{i n s c r}}$$

refers to a measure of the deviation of a triangular mesh face with respect to a reference equilateral triangle, where R_{circum} and r_{inscr} are the circumscribed and inscribed radii, respectively. 1≤ρ≤∞ where the higher the value, the greater the deviation.

Projection Factor (PF) refers to the percentage of mesh vertices on a given surface mesh that are clearly locally thin. 0≤PF≤1, where 0 means that no surface mesh vertices belong to any thin section, and 1 means that all of the surface mesh vertices are thin.

This leads to two definitions of what is thin and what is not thin in a fuzzy sense for a section of a surface mesh:
1. If (SS/t is large AND TT/t is large)—the section is thin; and
2. If (ρ_{source} is large AND β_{target} is large)—the section is not thin.

Statement 1 identifies sections as thin where the thickness gets smaller, and statement 2 assumes that highly stretched triangles may correspond to mesh faces located over model surfaces defining the sides of the thin sections. The meaning of “large” for both SS/t and TS/t may be given a standard lower bound of 2, however, two variable and independent reference values are applied in the method of the embodiments (where S is the local mesh size):

$${( \frac{S}{t} )}_{a} = \frac{2}{{e}^{- σ} + 1} \\ and \\ {( \frac{S}{t} )}_{b} = \frac{2}{{e}^{- \overline{PF}} + 1}$$

where σ is defined as the standard deviation of the S/t ratio over the surface mesh, and

$$\overline{PF} = \frac{1 - P F}{max ( ε , P F )}$$

with ε having a small value set to 10⁻⁴.

This leads to:

$$PF \to \overline{PF} : [ 0 , 1 ] \to [ \frac{1}{ε} , 0 ]$$

$$Hence :$$

$$σ \to {( \frac{S}{t} )}_{a} : [ 0 , ∞ ] \to [ 1 , 2 ] and PF \to {( \frac{S}{t} )}_{a b} : [ 0 , 1 ] \to [ 2 , 1 ]$$

such that the lower bound is reduced to consider SS/t and TS/t as large toward the value 1 whenever the standard deviation of such ratios is small (the thickness is nearly constant assuming that the surface mesh sizing is given), or nearly all vertices have been successfully projected (the section is almost completely marked as thin).

These conditions may enforce the section thinness, otherwise the lower bound for the large ratios tends towards a default value j. Initially, this default value is set at 2. The value of SS/t and TS/t represent whether a section is regarded as “thin” when they reach a “reasonably large” value. However, it may be desirable to represent this default value j as changing over time to be meaningful for the specific surface being modelled. For sections with a constant thickness, it is more likely that such sections may be considered “thin,” and therefore the default value j tends to a value of 1. This adds a further “fuzzy” variable into the model. Similarly, the value of \vec{P}F may be considered another fuzzy variable.

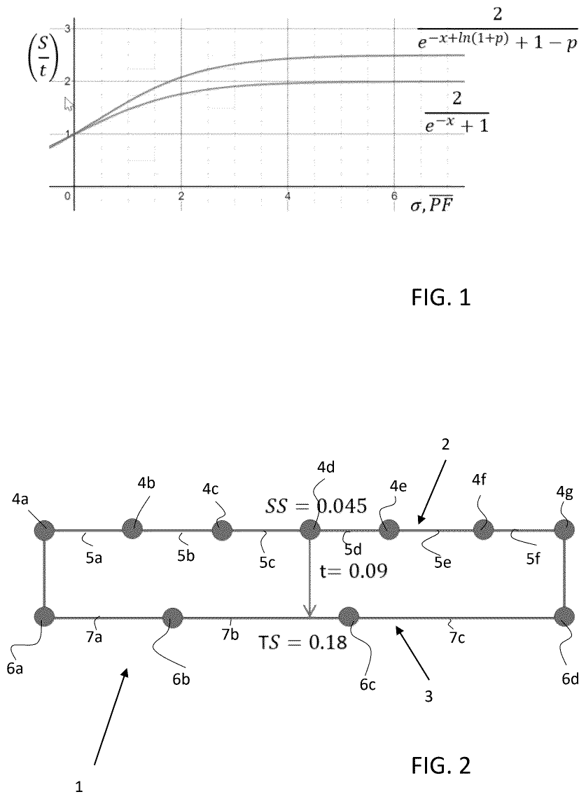

Turning back to FIG. 1, the value of S/t may change due to the variation in value 2

$$\frac{2}{{e}^{- x + ln ( 1 + p ) + 1 - p}} ,$$

where for zero values of \vec{PF}, the value of S/t may be greater than 1 for the section to be regarded as thin, and when the value of \vec{PF} is around 6, the value of S/t may be greater than 2.5 for the section to be regarded as thin. The projection factor PF has a value of 0 initially as at each vertex, no adjacent vertex is projected to a new position as part of the determination of the thinness of the section. However, as the investigation of this thinness continues, eventually all of the adjacent vertices have been projected if the section is determined to be thin, such that the projection factor PF=1.

Each of the above expressions for the ratio are modified to increase the fuzziness of the calculation:

$${( \frac{S}{t} )}_{a} = \frac{2}{{e}^{- σ + ln ( 1 + p )} + 1 - p}$$

$$and$$

$${( \frac{S}{t} )}_{b} = \frac{2}{{e}^{- \overline{PF} + ln ( 1 + p )} + 1 - p}$$

where p is a penalty factor for large values of σ and P̅F̅ and is set to a value of 0.2.

The role of this is illustrated in FIG. 1, which is a plot showing values of (S/t) against (σ, \vec{FP}). The purpose of the parameter p is to increase the asymptotic value of the lower bound, so that sections with highly irregular thickness (large σ) or with very few thin regions (large P̅F̅→small PF) are penalized with respect to the thin condition.

This leads to the final three statements employed in the embodiments:
1a if

$$( ( \frac{S S}{t} ) \geq {( \frac{s}{t} )}_{a} AND ( \frac{T S}{t} ) \geq {( \frac{S}{t} )}_{a} ) ,$$

then the section is thin in a fuzzy sense;
1b if

$$( ( \frac{S S}{t} ) \geq {( \frac{s}{t} )}_{b} AND ( \frac{T S}{t} ) \geq {( \frac{S}{t} )}_{b} ) ,$$

then the section is thin in a fuzzy sense;
2 if (ρ_{source}≥ρ̅ORρ_{target}≥β̅) where ρ̅=1.8 as the lower bound for large values of ρ, the section is not thin in a fuzzy sense.

### Mamdani's Scheme for Thin Meshing

An example in accordance with the embodiments of the method is shown in FIG. 2. FIG. 2 is an example of a mesh section where the thinness needs to be determined. The mesh section 1 includes a first surface mesh 2 and a second surface mesh 3 spaced apart from one another. The first surface mesh 2 includes a number of mesh vertices 4a,b,c,d,e,f,g separated from one another by a number of mesh faces 5a,b,c,d,e,f. The second surface mesh 3 includes a number of mesh vertices 6a,b,c,d separated from one another by a number of mesh faces 7a,b,c. The size of the local mesh at the source point S is given by the source sizing SS of 0.045 size units. The size of the local mesh at the target point T is given by the target sizing TS of 0.18 size units. The thickness t of the section 1, which is equal to the spacing between the first surface mesh 2 and the second surface mesh 3 is 0.09 size units. Using the equations above, this provides the values:

$$\frac{S S}{t} = \frac{0.045}{0.09} = 0.5 , \frac{T S}{t} = \frac{0.18}{0.09} = 2 , {ρ}_{source} = 1.3 , {ρ}_{target} = 1.5$$

Depending on the values of a (which is related to the geometry of the mesh and its discretization) and PF (which is related to how much the section has already been detected as thin when this check is performed) different scenarios may occur. For this example, the following values are considered:

$$p = 0.2 , σ = 0.01 , PF = 0.1 \to \overline{PF} = 9$$

$$such that :$$

$${( \frac{S}{t} )}_{a} = \frac{2}{{e}^{- 0.01 + ln ( 1.2 )} + 0.8} \approx \frac{2}{1.988} \approx 1.006$$

$${( \frac{S}{t} )}_{b} = \frac{2}{{e}^{- \overline{PF} + ln ( 1.2 )} + 0.8} \approx \frac{2}{0.8} \approx 2.5$$

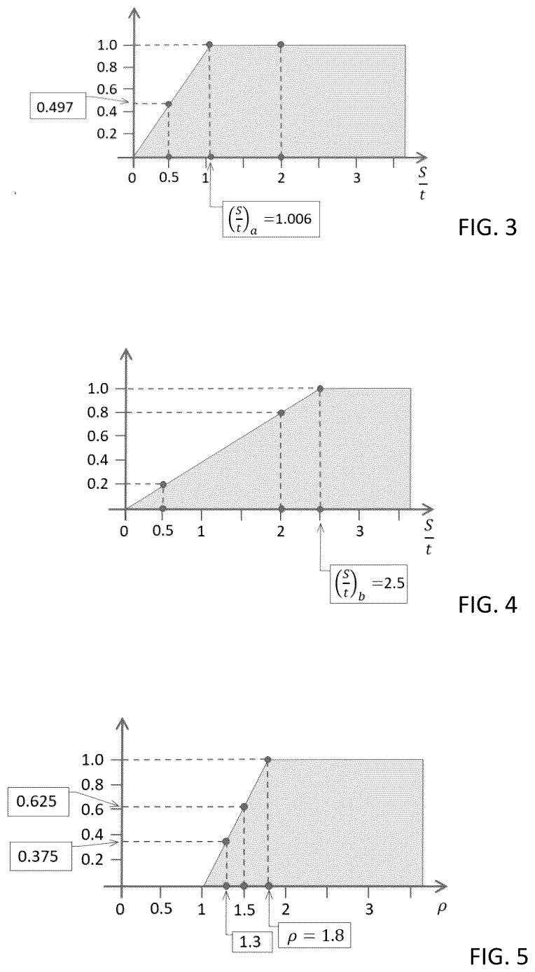

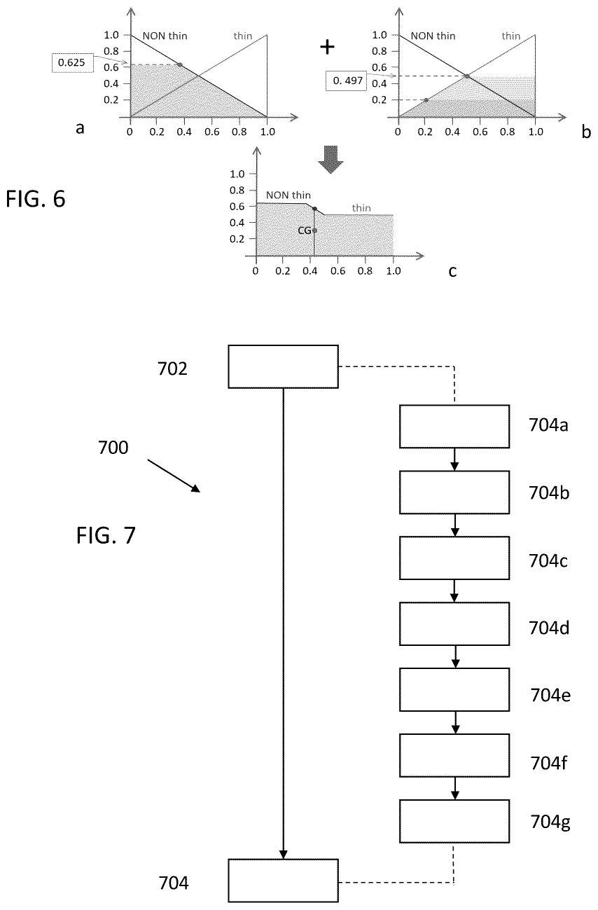

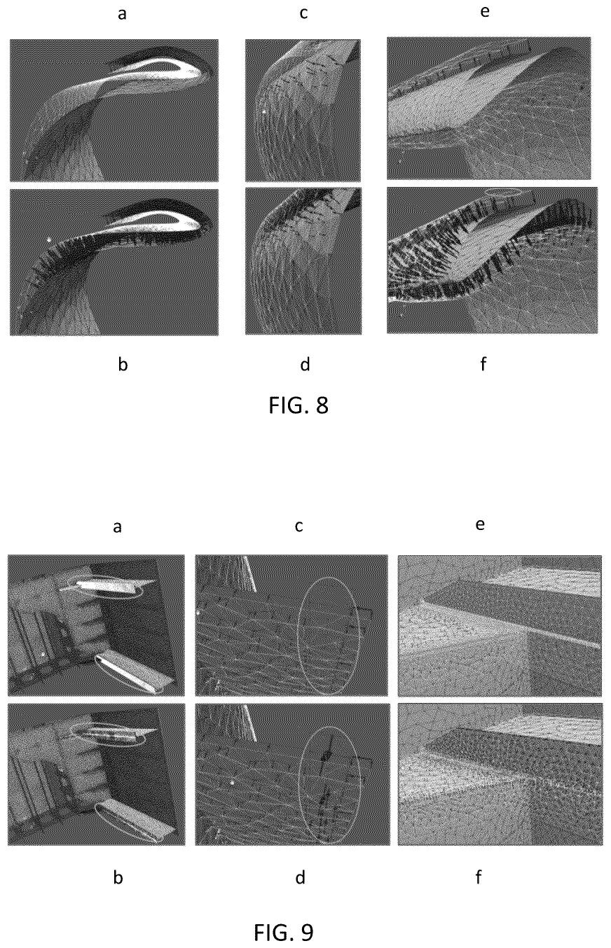

FIG. 3 is a plot of a first membership function for a property that “is thin” in accordance with embodiments of the present disclosure. The value of (S/t)_{β} is plotted along the x-axis, such that the value of 1.006 on the x-axis is plotted at a value of 1 on the y-axis. Reading off the value of

$$\frac{SS}{t} = 0.5$$

on the x-axis provides a y-axis value of 0.497, and that of

$$\frac{T S}{t} = 2$$

provides a y-axis value of 1.

FIG. 4 is a plot of a second membership function for the property “is thin” in accordance with embodiments of the present disclosure. The value of (S/t)_{b} is plotted along the x-axis, such that the value of 2.5 on the x-axis is plotted at a value of 1 on the y-axis. Reading off the value of

$$\frac{SS}{t} = 0.5$$

on the x-axis provides a y-axis value of 0.2, and that of

$$\frac{T S}{t} = 2$$

provides a y-axis value of 0.8.

Applying the fuzzy logic AND operator to determine whether or not the section is thin provides the following:
1a if (SS/t) is 49.7% thin AND(TS/t) is 100% thin—the section is 49.7% thin;
1b if (SS/t) is 20% thin AND(TS/t) is 80% thin—the section is 20% thin

For the second statement, the values of ρ_{source} and ρ_{target} (1.3 and 1.5 respectively) may be plotted in a similar manner.

FIG. 5 is a plot of a membership function for the property “is not thin” in accordance with embodiments of the present disclosure. Plotting ρ on the x-axis, with the upper bound of ρ given as 1.8 and equating to a value of 1 on the y-axis, the value of ρ_{source} of 1.3 gives a value on they-axis of 0.375, and the value of ρ_{target} 1.5 gives a value of 0.625 on the y-axis. The second statement then gives:
2 (ρ_{source} is 37.5% non-thin OR ρ_{target} is 62.5% non-thin)− the section is 62.5% non-thin

The final relationship (i.e., thin or non-thin) is given by combining two charts as shown in FIGS. 6a,b, and c. FIG. 6a is a plot of non-thin vs thin based on the value of the membership function for non-thin, and FIG. 6b is a plot of non-thin vs thin based on the values of the membership functions for thin. Plotting the values found by analyzing the first and second statements above and combining the charts gives FIG. 6c, the combined plot of non-thin and thin for the location under analysis. FIG. 6c is the union of FIGS. 6a and 6b, and taking the centroid of the area underneath the line is the standard method of determining the crisp value for thin or non-thin, which for the location under analysis falls within the non-thin section of the plot, hence at this location the mesh has to be considered non-thin.

FIG. 7 is a flowchart of a method in accordance with the embodiments of the present disclosure. The method 700 begins, at act 702, by selecting a volume region lying between a first surface mesh having a first set of mesh parameters and a second surface mesh having a second set of mesh parameters. The volume region has a thickness t corresponding to the distance between the first and second surface mesh.

If the volume region is thin, at act 704, a prismatic cell volume mesh is generated to fill the entire volume region. As outlined above, whether or not the volume region is thin is given by a crisp value calculated using a fuzzy logic inference scheme including the fuzzy sets thin and non-thin. The relationship between the first and second sets of mesh parameters and the thickness t determine the membership of the fuzzy sets thin and non-thin.

In sub-act 704a, a source point S is selected on the first surface mesh where the volume mesh is required and the surface mesh size SS at the source point is measured.

In sub-act 704b, a deviation ρ_{S} of a triangle of the surface mesh at the source point S from a reference equilateral triangle is calculated.

In sub-act 704c, a target point T is selected on the second surface mesh by extending a ray along the local normal from the source point, and the surface mesh size TS at the target point is measured.

In sub-act 704d, a deviation ρ_{T} of a triangle of the surface mesh at the target point T from a reference equilateral triangle is calculated. If the ratios SS/t and TS/t are above a first reference value and a second reference value, the volume region is in the thin fuzzy set, and wherein if the deviation ρ_{S} or the deviation ρ_{T} is above a third reference value then the volume region is in the non-thin fuzzy set.

In sub-act 704e, plots representing the membership of the thin fuzzy set are combined with a plot representing the membership of the non-thin fuzzy set graphically using an OR operator.

In sub-act 704f, the center-of-weight of the area under the resulting curve of the combined plots is calculated.

In sub-act 704g, the center-of-weight is taken as the crisp value of whether the volume is thin or non-thin.

The method in accordance with embodiments of the present disclosure is particularly useful in determining whether a sheet or thin wall of an object in a CAx model is locally thin. This then avoids the generation of an arbitrary volume in the locally thin region, leading to more accurate results when modelling physical properties of materials and designed products. The comparison between determining whether or not regions are locally thin based on hardcoded sharp logic and the methods outlined above is illustrated in FIGS. 8a-f and 9a-f.

FIG. 8a is a perspective view of a three-dimensional curved thin sheet having meshed surfaces modelled using hardcoded tolerances. It may be seen that only a small section of the volume of the thin sheet has been determined to be locally thin. However, FIG. 8b is a perspective view of a three-dimensional curved thin sheet having meshed surfaces modelled using the embodiments. Here it may be seen that the majority of the volume of the thin sheet in view has been determined to be locally thin. FIG. 8c is an alternative perspective view of a portion of the thin sheet shown in FIG. 8a, and FIG. 8d is an alternative perspective view of a portion of the thin sheet shown in FIG. 8b. Similarly, FIG. 8e is an alternative perspective view of a portion of the thin sheet shown in FIG. 8a, and FIG. 8f is an alternative perspective view of a portion of the thin sheet shown in FIG. 8b. In each case, the embodiments have led to a greater volume of the thin sheet being determined to be thin, and therefore filled with a prismatic mesh.

FIG. 9a is a perspective view of a three-dimensional complex component having meshed surfaces modelled using hardcoded tolerances. Only a small section of the volume of the highlighted regions has been determined to be locally thin. However, FIG. 9b is a perspective view of a three-dimensional complex component having meshed surfaces modelled using the embodiments. Here it may be seen that the majority of the volume of the highlighted regions has been determined to be locally thin. FIG. 9c is an alternative perspective view of a portion of the component shown in FIG. 9a, and FIG. 9d is an alternative perspective view of a portion of the component shown in FIG. 9b. Similarly, FIG. 9e is an alternative perspective view of a portion of the component shown in FIG. 9a, and FIG. 9f is an alternative perspective view of a portion of the component shown in FIG. 9b. In each case, the embodiments have led to a greater volume of the component in different regions being determined to be thin, and therefore filled with a prismatic mesh.

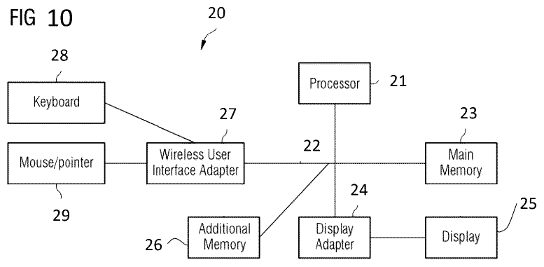

FIG. 10 illustrates an example of a data processing system in which an embodiment of the present disclosure may be implemented, for example, a CAx system configured to perform processes as described herein. The data processing system 20 includes a processor 21 connected to a local system bus 252. The local system bus connects the processor to a main memory 23 and graphics display adaptor 24, which may be connected to a display 25. The data processing system may communicate with other systems via a wireless user interface adapter connected to the local system bus 22, or via a wired network, for example, to a local area network. Additional memory 26 may also be connected via the local system bus. A suitable adaptor, such as wireless user interface adapter 27, for other peripheral devices, such as a keyboard 28 and mouse 29, or other pointing device, allows the user to provide input to the data processing system. These enable the selection of a region of a sheet or thin walled object for determination of the locally thin nature of a meshed volume. Other peripheral devices may include one or more I/O controllers such as USB controllers, Bluetooth controllers, and/or dedicated audio controllers (connected to speakers and/or microphones). Various peripherals may be connected to the USB controller (via various USB ports) including input devices (e.g., keyboard, mouse, touch screen, trackball, camera, microphone, scanners), output devices (e.g., printers, speakers), or any other type of device that is operative to provide inputs or receive outputs from the data processing system. Further, certain devices referred to as input devices or output devices may both provide inputs and receive outputs of communications with the data processing system. Further, other peripheral hardware connected to the I/O controllers may include any type of device, machine, or component that is configured to communicate with a data processing system.

An operating system included in the data processing system enables an output from the system to be displayed to the user on display 25 and the user to interact with the system. Examples of operating systems that may be used in a data processing system may include Microsoft Windows™, Linux™, UNIX™, iOS™, and Android™ operating systems.

In addition, the data processing system 20 may be implemented as in a networked environment, distributed system environment, virtual machines in a virtual machine architecture, and/or cloud environment. For example, the processor 21 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 20 may vary for particular implementations. For example the data processing system 20 in this example may correspond to a computer, workstation, and/or a server. However, alternative embodiments of a data processing system may be configured with corresponding or alternative components such as in the form of a mobile phone, tablet, controller board or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 20 may be connected to the network (not a part of data processing system 20), which may be any public or private data processing system network or combination of networks, as known to those of skill in the art, including the Internet. Data processing system 20 may communicate over the network with one or more other data processing systems such as a server (also not part of the data processing system 20). However, an alternative data processing system may correspond to a plurality of data processing systems implemented as part of a distributed system in which processors associated with several data processing systems may be in communication by way of one or more network connections and may collectively perform tasks described as being performed by a single data processing system. Thus, when referring to a data processing system, such a system may be implemented across several data processing systems organized in a distributed system in communication with each other via a network.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method of generating a volume mesh in a Computer-Aided technology model of an object, the method comprising:
selecting a volume region lying between a first surface mesh having a first set of mesh parameters and a second surface mesh having a second set of mesh parameters, wherein the volume region comprises a thickness corresponding to a distance between the first surface mesh and the second surface mesh; and
generating a prismatic cell volume mesh to fill an entirety of the volume region when the volume region is thin,
wherein a crisp value is calculated to determine whether the volume region is thin using a fuzzy logic inference scheme comprising fuzzy sets thin and non-thin, and
wherein a relationship between the first and second sets of mesh parameters and the thickness determine membership of the fuzzy sets thin and non-thin.

2. The method of claim 1, wherein determining the membership of the fuzzy sets comprises:
selecting a source point S on the first surface mesh where the volume mesh is required, measuring a first surface mesh size SS at the source point, and calculating a deviation ρs of a triangle of the first surface mesh at the source point S from a reference equilateral triangle; and
selecting a target point T on the second surface mesh by extending a ray along a local normal from the source point, measuring a second surface mesh size TS at the target point and calculating a deviation β_{T} of a triangle of the second surface mesh at the target point T from a reference equilateral triangle,
wherein the volume region is in the thin fuzzy set when ratios SS/t and TS/t are above a first reference value and a second reference value, and
wherein the volume region is in the non-thin fuzzy set when the deviation ρ_{S} or the deviation ρ_{T} is above a third reference value.

3. The method of claim 2, wherein the first reference value is given by:
$${( \frac{S}{t} )}_{a} = \frac{2}{{e}^{- σ + ln ( 1 + p )} + 1 - p}$$
wherein the second reference value is given by:
$${( \frac{S}{t} )}_{b} = \frac{2}{{e}^{- \overline{PF} + ln ( 1 + p )} + 1 - p}$$
wherein the third reference value is given by:
$$\overline{ρ} = 1.8$$
wherein:
S is a local mesh size of the first surface mesh,
t is the thickness of the volume region,
σ is a standard deviation of a S/t ratio over a surface of the first surface mesh,
P̅F̅ is
$$\frac{1 - PF}{max ( ε , PF )} ,$$
where ε=10⁻⁴ is a percentage of verticles on the first surface mesh that are locally thin, and
p is a penalty factor.

4. The method of claim 3, further comprising:
combining plots representing the membership of the thin fuzzy set with a plot representing the membership of the non-thin fuzzy set graphically using an OR operator;
calculating a center-of-weight of an area under a curve of the combined plots; and
taking the center-of-weight as the crisp value.

5. The method claim 1, wherein the object comprises a thin sheet or a thin wall.

6. The method claim 1, wherein the computer-aided technology model is a computational fluid dynamics model.

7. The method claim 1, wherein the fuzzy logic inference scheme is a Mamdani inference scheme.

8. The method of claim 1, wherein the volume mesh does not contain arbitrary volume cells.

9. A computer program comprising instructions that, when executed by a computer processor of a computer, cause the computer to:
select a volume region lying between a first surface mesh having a first set of mesh parameters and a second surface mesh having a second set of mesh parameters, wherein the volume region comprises a thickness corresponding to a distance between the first surface mesh and the second surface mesh; and
generate a prismatic cell volume mesh to fill an entirety of the volume region when the volume region is thin,
wherein a crisp value is calculated to determine whether the volume region is thin using a fuzzy logic inference scheme comprising fuzzy sets thin and non-thin, and
wherein a relationship between the first and second sets of mesh parameters and the thickness determine membership of the fuzzy sets thin and non-thin.

10. A data processing system configured to generate a thin volume mesh in a Computer-Aided technology model of an object, the data processing system comprising:
an input device configured to receive a selection of a volume region lying between a first surface mesh having a first set of mesh parameters and a second surface mesh having a second set of mesh parameters, wherein the volume region comprises a thickness corresponding to a distance between the first surface mesh and the second surface mesh; and
a processor configured to generate a prismatic cell volume mesh to fill an an entirety of the volume region,
wherein a crisp value is calculated by the processor to determine whether the volume region is thin using a fuzzy logic inference scheme comprising fuzzy sets thin and non-thin, and
wherein a relationship between the first and second sets of mesh parameters and the thickness determine membership of the fuzzy sets thin and non-thin.
